(19) United States
(12) Patent Application Publication
(10) Pub. No.: US 2015/0325273 A1
(43) Pub. Date: Nov. 12, 2015

(54) Discrete Three-Dimensional Vertical Memory

(71) Applicant: Guobiao ZHANG, Corvallis, OR (US)

(72) Inventor: Guobiao ZHANG, Corvallis, OR (US)

(21) Appl. No.: 14/803,104

(22) Filed: Jul. 19, 2015

Related U.S. Application Data
(63) Continuation-in-part of application No. 14/636,359, filed on Mar. 3, 2015, now Pat. No. 9,123,393.
Application No. 14/636,359 is a continuation-in-part of application No. 14/047,011, filed on Oct. 6, 2013, now Pat. No. 9,093,129.
Application No. 14/047,011 is a continuation-in-part of application No. 13/787,787, filed on Mar. 6, 2013, now Pat. No. 8,890,300.
Application No. 13/787,787 is a continuation-in-part of application No. 13/591,257, filed on Aug. 22, 2012, now Pat. No. 8,921,991.
(60) Provisional application No. 61/529,929, filed on Sep. 1, 2011.

(51) Int. Cl. G11C 5/02; G11C 8/00; G11C 7/00

(52) U.S. Cl. CPC G11C 5/025; G11C 7/00; G11C 8/00

(57) ABSTRACT

The present invention discloses a discrete three-dimensional vertical memory (3D-M_{V}). It comprises at least a 3D-array die and at least a peripheral-circuit die. The 3D-array die comprises a plurality of vertical memory strings. At least an off-die peripheral-circuit component for the 3D-M_{V} arrays is located on the peripheral-circuit die instead of the 3D-array die. The 3D-array die and the peripheral-circuit die have substantially different back-end-of-line (BEOL) structures.

### CROSS-REFERENCE TO RELATED APPLICATIONS

This is a continuation-in-part of application “Discrete Three-Dimensional Vertical Memory”, application Ser. No. 14/636,359, filed Mar. 3, 2015, which is a continuation-in-part of application “Discrete Three-Dimensional Memory Comprising Dice with Different BEOL Structures”, application Ser. No. 14/047,011, filed Oct. 6, 2013, which is a continuation-in-part of application “Discrete Three-Dimensional Memory Comprising Off-Die Read/Write-Voltage Generator”, application Ser. No. 13/787,787, filed Mar. 6, 2013, which is a continuation-in-part of application “Discrete Three-Dimensional Memory”, application Ser. No. 13/591,257, filed Aug. 22, 2012, which claims benefit of a provisional application “Three-Dimensional Memory with Separate Memory-Array and Peripheral-Circuit Substrates”, Application Ser. No. 61/529,929, filed Sep. 1, 2011.

### BACKGROUND

1. Technical Field of the Invention

The present invention relates to the field of integrated circuit, and more particularly to three-dimensional vertical memory (3D-M_{V}).

2. Prior Arts

Three-dimensional memory (3D-M) is a monolithic semiconductor memory comprising a plurality of vertically stacked memory cells. It includes three-dimensional read-only memory (3D-ROM) and three-dimensional random-access memory (3D-RAM). The 3D-ROM can be further categorized into three-dimensional mask-programmed read-only memory (3D-MPROM) and three-dimensional electrically-programmable read-only memory (3D-EPROM). 3D-M may further be a 3D-memristor, 3D-RRAM or 3D-ReRAM (resistive random-access memory), 3D-PCM (phase-change memory), 3D-PMC (programmable metallization-cell memory), or 3D-CBRAM (conductive-bridging random-access memory).

U.S. Pat. No. 5,835,396 issued to Zhang on Nov. 3, 1998 discloses a 3D-M, more particularly a 3D-ROM. As illustrated in FIG. 1A, a 3D-M die 20 comprises a substrate-circuit level 0K and a plurality of vertically stacked memory levels 16A, 16B. The substrate-circuit level 0K comprises substrate transistors 0t and substrate interconnects 0i. The substrate transistors 0t are formed in a semiconductor substrate 0. The substrate interconnects 0i are the interconnects for the substrate transistor 0t. In this example, the substrate interconnects 0i includes metal layers 0M1, 0M2. Hereinafter, the metal layers 0M1, 0M2 in the substrate interconnects 0i are referred to as substrate interconnect layers; the materials used in the substrate interconnects 0i are referred to as substrate interconnect materials.

The memory levels 16A, 16B are stacked above the substrate-circuit level 0K. They are coupled to the substrate 0 through contact vias (e.g., 1 av). Each of the memory levels (e.g., 16A) comprises a plurality of upper address lines (e.g., 2a), lower address lines (e.g., 1a) and memory cells (e.g., 5aa). The memory cells could comprise diodes, transistors or other devices. Among all types of memory cells, the diode-based memory cells are of particular interest because they have the smallest size of ˜4 F², where F is the minimum feature size. Since they are generally located at the cross points between the upper and lower address lines, the diode-based memory cells form a cross-point array. Hereinafter, diode is broadly interpreted as any two-terminal device whose resistance at the read voltage is substantially lower than when the applied voltage has a magnitude smaller than or polarity opposite to that of the read voltage. In one exemplary embodiment, diode is a semiconductor diode, e.g., p-i-n silicon diode. In another exemplary embodiment, diode is a metal-oxide diode, e.g., titanium-oxide diode, nickel-oxide diode.

The memory levels 16A, 16B form at least a 3D-M array 16, while the substrate-circuit level 0K comprises the peripheral circuit for the 3D-M array 16. A first portion of the peripheral circuit is located underneath the 3D-M array 16 and it is referred to as under-array peripheral circuit. A second portion of the peripheral circuit is located outside the 3D-M array 16 and it is referred to as outside-array peripheral circuits 18. Because the outside-array peripheral circuit 18 comprises significantly fewer back-end-of-line (BEOL) levels than the 3D-M array 16, the space 17 above the outside-array peripheral circuits 18 is empty and completely wasted. Hereinafter, a BEOL level refers to a level of conductive lines above the substrate. In FIG. 1A, the 3D-M array 16 comprises a total of six BEOL levels, including the two interconnect levels 0M1, 0M2, two address-line levels 1a, 2a for the first memory level 16A, and two address-line levels 3a, 4a for the second memory level 16B. The outside-array peripheral circuit 18 comprises only two BEOL levels, i.e., the interconnect levels 0M1, 0M2.

U.S. Pat. No. 7,383,476 issued to Crowley et al. on Jun. 3, 2008 discloses an integrated 3D-M die, whose 3D-arrays and peripheral circuit are integrated on a single die. As is illustrated in FIG. 1B, an integrated 3D-M die 20 comprises a 3D-array region 22 and a peripheral-circuit region 28. The 3D-array region 22 comprises a plurality of 3D-M arrays (e.g., 22aa, 22ay) and their decoders (e.g., 24, 24G). These decoders include local decoders 24 and global decoders 24G. The local decoder 24 decodes address/data for a single 3D-M array, while the global decoder 24G decodes global address/data 25 to each 3D-M array.

The peripheral-circuit region 28 comprises all necessary peripheral-circuit components for a standalone integrated 3D-M die 20 to perform basic memory functions, i.e., it can directly use the voltage supply 23 provided by a user (e.g., a host device or a controller), directly read data 27 from the user and directly write data 27 to the user. It includes a read/write-voltage generator (V_{R}/V_{W}-generator) 21 and an address/data (A/D)-translator 29. The V_{R}/V_{W}-generator 21 provides read voltage V_{R} and/or write (programming) voltage V_{W} to the 3D-M array(s). The A/D-translator 29 converts address and/or data from a logical space to a physical space and/or vice versa. Hereinafter, the logical space is the space viewed from the perspective of a user of the 3D-M, while the physical space is the space viewed from the perspective of the 3D-M.

The example in FIGS. 1A-1B is a three-dimensional horizontal memory (3D-M_{H}), whose basic storage units are horizontal memory levels. The above description can also be applied to a three-dimensional vertical memory (3D-M_{V}), whose basic storage units are vertical memory strings.

U.S. Pat. No. 8,638,611 issued to Sim et al. on Jan. 28, 2014 discloses a 3D-M_{V}. It is a vertical-NAND. Besides vertical-NAND, the 3D-ROM, 3D-RAM, 3D-memristor, 3D-ReRAM or 3D-RRAM, 3D-PCM, 3D-PMC, 3D-CBRAM can also be arranged into 3D-M_{V}. As illustrated in FIG. 2, a 3D-M_{V} die 20 comprises at least a 3D-M_{V} array 16 and a peripheral circuit 18. The 3D-M_{V} array 16 comprises a plurality of vertical memory strings 16X, 16Y. Each memory string (e.g., 16X) comprises a plurality of vertically stacked memory cells (e.g., 8a-8h). These memory cells are coupled by at least a vertical address line. Each memory cell (e.g., 8f) comprises at least a vertical transistor, with a gate 6, an information storage layer 7 and a vertical channel 9. The gate 6 of each memory cell (e.g., 8f) on a vertical memory string forms a BEOL level. In this example, the 3D-M_{V} array 16 comprises eight BEOL levels, i.e., the memory levels 8a-8h.

In some 3D-M_{V}'s, at least a portion of its peripheral circuit is formed underneath the 3D-M_{V} arrays (similar to the 3D-M_{H} 20 of FIG. 1A). In other 3D-M_{V}'s, all of its peripheral circuit is formed outside the 3D-M_{V} arrays (FIG. 2). The peripheral circuit 18 for the 3D-M_{V} array 16 comprises substrate transistors 0t and substrate interconnects 0i. The substrate transistors 0t are conventional (horizontal) transistors formed in the semiconductor substrate 0. The substrate interconnects 0i are the interconnects for the substrate transistor 0t. In this example, the peripheral circuit 18 comprises two BEOL levels, i.e., the interconnect levels 0M1, 0M2.

The prior-art 3D-M_{V} is an integrated 3D-M_{V}, whose 3D-M_{V} array 16 and peripheral circuit 18 are integrated into a single 3D-M_{V} die 20. Because their manufacturing processes are not compatible, the 3D-M_{V} array 16 and its peripheral circuit 18 are formed separately. Accordingly, the 3D-M_{V} die 20 of FIG. 2 comprises ten BEOL levels, including eight memory levels for the 3D-M_{V} array 16 and two interconnect levels for the peripheral circuit 18.

It is a prevailing belief in the field of integrated circuit that more integration is better, because integration lowers cost and improves performance. However, this belief is no longer true for 3D-M_{V}. First of all, because the vertical memory strings 16X, 16Y comprises significantly more BEOL levels than the peripheral circuit 18, integrating would force a relatively simple peripheral circuit 18 to use the expensive BEOL manufacturing process of the 3D-M_{V} array 16. This increases the overall 3D-M_{V} cost. Secondly, as the 3D-M_{V} 20 is optimized for its 3D-M_{V} array 16, the performance of its peripheral circuit 18 is sacrificed. For example, the peripheral circuit 18 comprises high-temperature interconnect materials (i.e., the interconnect materials which are compatible with high processing temperatures, e.g., tungsten for conductive material and silicon oxide for insulating material). Because their speed is generally slower, the high-temperature interconnect materials degrade the overall 3D-M_{VF} performance.

### OBJECTS AND ADVANTAGES

It is a principle object of the present invention to provide a three-dimensional vertical memory (3D-M_{V}) with a lower overall cost.

It is a further object of the present invention to provide a 3D-M_{V} with an improved overall performance.

In accordance with these and other objects of the present invention, a discrete 3D-M_{V} is disclosed.

### SUMMARY OF THE INVENTION

To lower the overall 3D-M_{V} cost and/or improve the overall 3D-M_{V} performance, the present invention follows this design guideline: separate the 3-D circuit and 2-D circuit into different dice in such a way that they could be optimized separately. For example, the 3D-M_{V} array (3-D circuit) and at least a peripheral-circuit component thereof (2-D circuit) are separated into different dice. Accordingly, the present invention discloses a discrete 3D-M_{V}. It comprises at least a 3D-array die and at least a peripheral-circuit die. The 3D-array die is formed in a 3-D space and comprises a plurality of functional levels. It comprises at least a 3D-M_{V} array and at least a first peripheral circuit thereof, which is referred to as the in-die peripheral circuit. The peripheral-circuit die is formed on a 2-D plane and comprises just a single functional level. It comprises at least a second peripheral circuit of the 3D-M_{V} array, which is referred to as the off-die peripheral circuit. This off-die peripheral circuit is an essential circuit for the 3D-M_{V} to perform basic memory functions, e.g., directly using the voltage supply provided by a user, directly reading data from the user and directly writing data to the user. It could be a read/write-voltage generator (V_{R}/V_{W}-generator), an address/data translator (A/D-translator), a portion of the V_{R}/V_{W}-generator, and/or a portion of the A/D-translator. Without this off-die peripheral circuit, the 3D-array die per se is not a functional memory.

Designed and manufactured separately, the 3D-array die and the peripheral-circuit die in a discrete 3D-M_{V} could have substantially different back-end-of-line (BEOL) structures. First of all, the peripheral-circuit die could comprise substantially fewer BEOL levels than the 3D-array die in such a way that the peripheral-circuit die has a much lower wafer cost than the 3D-array die. In one preferred embodiment, the number of memory cells on a memory string in the 3D-array die is substantially more than the number of interconnect levels in the peripheral-circuit die. Accordingly, the discrete 3D-M_{V} has a lower overall cost than the integrated 3D-M_{V}. Secondly, the BEOL structures of the peripheral-circuit die could be independently optimized in such a way that the off-die peripheral-circuit component has a better performance than the same peripheral-circuit component in the integrated 3D-M_{V}. For example, the off-die peripheral-circuit component on the peripheral-circuit die comprises high-speed interconnect materials (e.g., copper for conductive material and high-k dielectric for insulating material), which are generally faster than the in-die peripheral-circuit component on the 3D-array die which comprises high-temperature interconnect materials. Accordingly, the discrete 3D-M_{V} has a better overall performance than the integrated 3D-M_{V}.

### BRIEF DESCRIPTION OF THE DRAWINGS

FIG. 1A is a cross-sectional views of an integrated three-dimensional horizontal memory (3D-M_{H}) (prior art); FIG. 1B is a block diagram of an integrated 3D-M_{H} die (prior art);

FIG. 2 is a cross-sectional view of an integrated three-dimensional vertical memory (3D-M_{V}) (prior art);

FIGS. 3A-3D illustrate four preferred discrete 3D-M_{V}'s;

FIG. 4A is a cross-sectional view of a preferred 3D-array die; FIG. 4B is a cross-sectional view of a preferred peripheral-circuit die;

FIGS. 5A-5B disclose a first preferred partitioning scheme;

FIGS. 6A-6B disclose a second preferred partitioning scheme;

FIGS. 7A-7C disclose a third preferred partitioning scheme;

FIGS. 8A-8B disclose a fourth preferred partitioning scheme;

FIGS. 9A-9B are block diagrams of two preferred peripheral-circuit dice supporting multiple 3D-array dice;

FIGS. 10A-10B are cross-sectional views of two preferred discrete 3D-M_{V} packages; FIG. 10C is a cross-sectional view of a preferred discrete 3D-M_{V} module.

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

In the present invention, the symbol “/” means a relationship of “and” or “or”. For example, the read/write-voltage generator (V_{R}/V_{W}-generator) could generate either only the read voltage, or only the write voltage, or both the read voltage and the write voltage. In another example, the address/data (A/D)-translator could translate either only address, or only data, or both address and data.

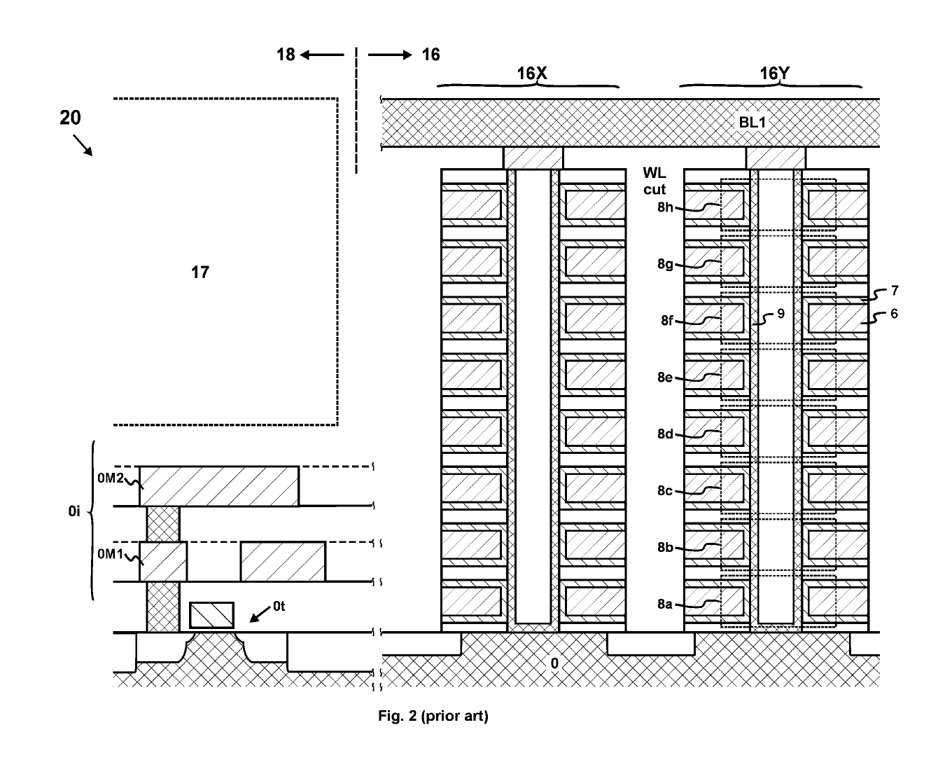

Referring now to FIGS. 3A-3D, four preferred discrete three-dimensional vertical memory (3D-M_{V}) 50 are disclosed. The discrete 3D-M_{V} 50 includes a physical interface 54 according to a standard for connecting to a variety of hosts. Physical interface 54 includes individual contacts 52a, 52b, 54a-54d that connect with corresponding contacts in a host receptacle. The power-supply contact 52a is provided to connect to a power-supply contact in the host receptacle. The voltage supplied by the host to power-supply contact 52a is referred to as voltage supply V_{DD}. The ground contact 52b provides a ground connection at a voltage V_{SS}. The contacts 54a-54d provide signal connections between the host and the discrete 3D-M_{V} 50. The signals represented on the contacts 54a-54d include address and data, among others. Because they are directly to/from the host, the address and data represented on the contacts 54a-54d are logical address and logical data.

The discrete 3D-M_{V} 50 comprises at least a 3D-array die 30 and at least a peripheral-circuit die 40/40*. In these figures, at least an off-die peripheral-circuit component of the 3D-M_{V} is located on the peripheral-circuit die 40/40* instead of the 3D-array die 30. This off-die peripheral circuit is an essential circuit for the 3D-M_{V} to perform basic memory functions, e.g., directly using the voltage supply provided by a user, directly reading data from the user and directly writing data to the user. It could be a read/write-voltage generator (V_{R}/V_{W}-generator), an address/data translator (A/D-translator), a portion of the V_{R}/V_{W}-generator, and/or a portion of the A/D-translator. Without this off-die peripheral circuit, the 3D-array die 30 per se is not a functional memory.

The preferred discrete 3D-M_{V} 50 in FIG. 3A is in the form of a memory card. Its peripheral-circuit die 40 comprises an off-die V_{R}/V_{W}-generator, which receives a voltage supply V_{DD} from the power-supply contact 52a and provides the 3D-array die 30 with at least a read/write voltage through a power bus 56. The read/write voltage includes at least a read voltage and/or a write voltage other than the voltage supply V_{DD}. In other words, it could be either at least a read voltage V_{R}, or at least a write voltage V_{W}, or both read voltage V_{R} and write voltage V_{W}, and the values of these read voltages and write voltages are different from the voltage supply V_{DD}. In this preferred embodiment, the read/write voltage includes one read voltage V_{R} and two write voltages V_{W1}, V_{W2}. Alternatively, it could include more than one read voltage or more than two write voltages.

The preferred discrete 3D-M_{V} 50 in FIG. 3B is in the form of a memory card. Its peripheral-circuit die 40* comprises an off-die A/D-translator, which includes an address converter and/or a data converter. The address converter converts the logical address represented on the contacts 54a-54d to the physical address represented on an internal bus 58 and/or vice versa; the data converter converts the logical data represented on the contacts 54a-54d to the physical data represented on an internal bus 58 and/or vice versa. The A/D-translator could convert address only, data only, or both address and data.

The preferred discrete 3D-M_{V} 50 in FIG. 3C is in the form of a memory card. It comprises two peripheral-circuit dice: a peripheral-circuit die A 40 and a peripheral-circuit die B 40*. The peripheral-circuit die A 40 comprises an off-die V_{R}/V_{W}-generator and the peripheral-circuit die B 40* comprises an off-die A/D-translator.

The preferred discrete 3D-M 50 in FIG. 3D can be used for a high-capacity memory card or a solid-state drive. It comprises two peripheral-circuit dice 40, 40* and a plurality of 3D-array dice 30a, 30b . . . 30w. The peripheral-circuit die A 40 comprises an off-die V_{R}/V_{W}-generator and the peripheral-circuit die B 40* comprises an off-die A/D-translator. The 3D-array dice form two channels: Channel A and Channel B. The internal bus 58A on Channel A provides physical address/data to the 3D-array dice 30a, 30b . . . 30i, while the internal bus 58B on Channel B provides physical address/data to the 3D-array dice 30r, 30s . . . 30w. The power bus 56 provides the read/write-voltages to all 3D-array dice 30a, 30b . . . 30w. Although two channels are used in this example, it should be apparent to those skilled in the art that more than two channels may be used.

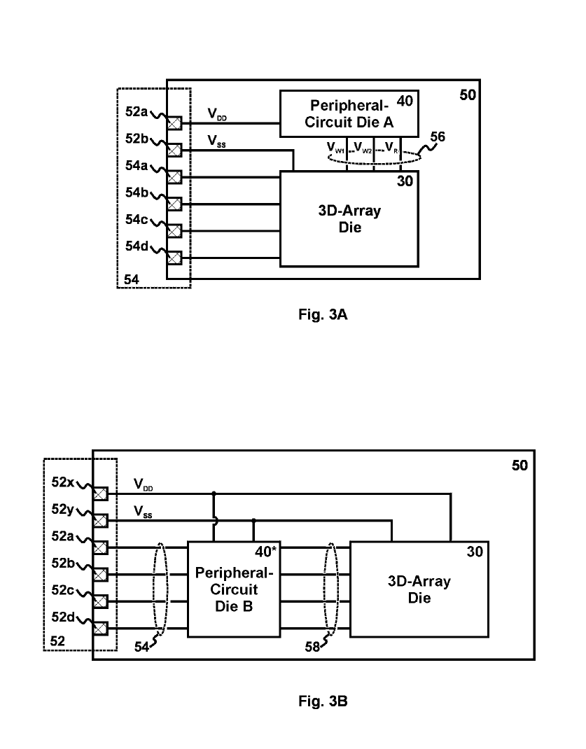

Referring now to FIG. 4A, a cross-sectional view of a preferred 3D-array die 30 is disclosed. It comprises at least a 3D-M_{V} array 36 and an in-die peripheral-circuit component 38. The 3D-M_{V} array 36 is formed in a 3-D space and comprises a plurality of vertical memory strings (e.g., 16X, 16Y). Each memory string (e.g., 16Y) comprises a plurality of vertically stacked memory cells (e.g., 8a-8h). These memory cells are coupled by at least a vertical address line. Each memory cell (e.g., 8f) comprises at least a vertical transistor, with gate 6, information storage layer 7 and channel 9. An exemplary memory cell is a vertical-NAND cell. For the 3D-M_{V} array 36, the number of BEOL levels is equal to the number of memory cells on a vertical memory string (e.g., 16X). Alternatively, the number of BEOL levels could be larger than the number of memory cells on a vertical memory string. The 3D-M_{V} array 36 of FIG. 4A comprises eight BEOL levels, i.e., the memory levels 8a-8h. A real-world 3D-M_{V} array could comprise 24 or more BEOL levels.

The in-die peripheral circuit 38 could be located outside the 3D-M_{V} array 36. Alternatively, at least a portion of the in-die peripheral circuit could be located underneath the 3D-M_{V} array. The in-die peripheral circuit 38 comprises substrate transistors 0t and substrate interconnects 0i. The substrate transistors 0t are conventional (horizontal) transistors formed in the semiconductor substrate 0. The substrate interconnects 0i are the interconnects for the substrate transistor 0t. In this preferred embodiment, the in-die peripheral circuit 38 comprises two BEOL levels, i.e., the interconnect levels 0M1, 0M2.

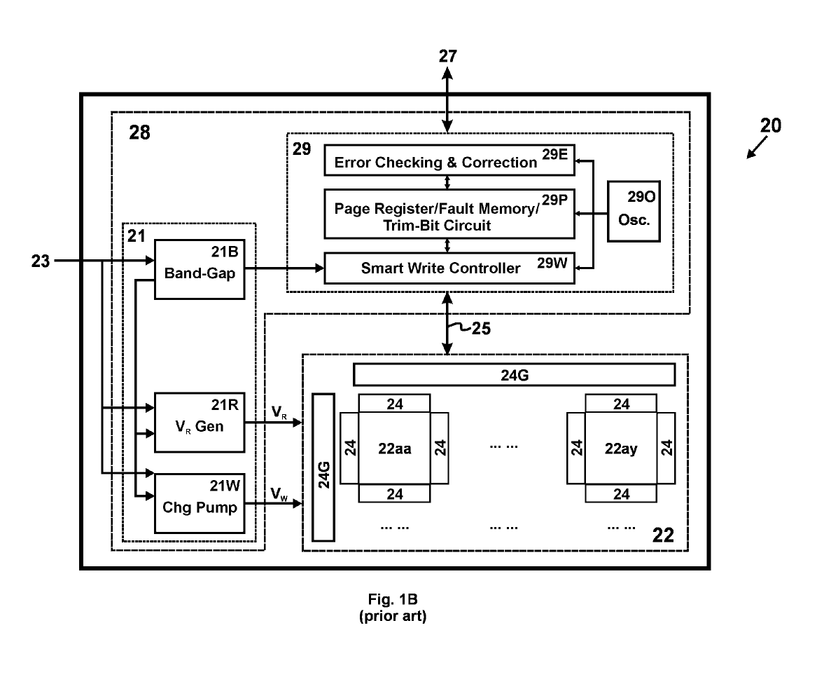

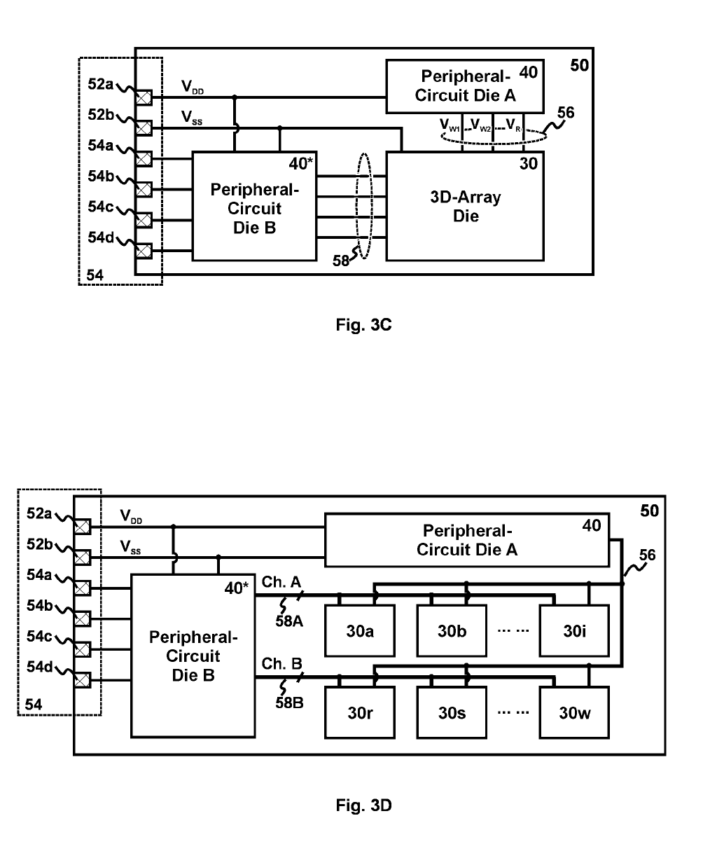

Although the cross-sectional view of FIG. 4A is similar to that of FIG. 2, the peripheral circuit 18 of FIG. 2 comprises all peripheral-circuit components of the integrated 3D-M_{V} 20, whereas at least one peripheral-circuit component of the discrete 3D-M_{V} 30 is absent from the in-die peripheral circuit 38 of FIG. 4A. For example, at least a V_{R}/V_{W}-generator and/or an A/D-translator is absent from the in-die peripheral circuit 38. Further details on the in-die peripheral circuit 38 are disclosed in FIGS. 5A-8B.

Referring now to FIG. 4B, a cross-sectional view of a preferred peripheral-circuit die 40 is disclosed. The peripheral-circuit die 40 is formed on a 2-D plane and includes a single functional level, i.e., the substrate-circuit level 0K′. The substrate-circuit level 0K′ comprises substrate transistors 0t′ and substrate interconnects 0i′. The substrate transistors 0t′ are formed in a peripheral-circuit substrate 0′. The substrate interconnects 0i′ are the interconnects for the substrate transistor 0t′. In this preferred embodiment, the peripheral-circuit die 40 comprises four BEOL levels, i.e., the interconnect levels 0M1′-0M4′.

It is known that the manufacturing cost of an integrated circuit is roughly proportional to the number of its BEOL levels. Comprising much fewer BEOL levels (4 vs. 8), the peripheral-circuit die 40 has a much lower wafer cost than the 3D-array die 30. Because at least a portion of the discrete 3D-M_{V} 50 (i.e., the off-die peripheral-circuit component) has a lower cost than that of the integrated 3D-M_{V} die 20, the discrete 3D-M_{V} 50 has a lower overall cost than the integrated 3D-M_{V} 20.

In addition, the peripheral-circuit die 40 could comprise more interconnect levels (4 vs. 2) than the peripheral circuit 38 because it is not part of the 3D-array die 30. With more interconnect levels, the off-die peripheral-circuit component on the peripheral-circuit die 40 is easier to design, have a better performance and occupy less chip area than that on the integrated 3D-M_{V} die 20. Note that, although it comprises more interconnect levels than the peripheral circuit 18, the peripheral-circuit die 40 still comprises significantly fewer BEOL levels (4 vs. 8) than the 3D-array die 30.

Furthermore, the peripheral-circuit die 40 may use high-speed interconnect materials for its interconnects 0i′ (e.g., copper for conductive materials and low-k dielectric for insulating materials), because it does not have to go through any high-temperature BEOL processing steps. These high-speed interconnect materials can improve the performance of the peripheral-circuit die 40 and in turn, improve the overall 3D-M_{V} performance.

For a conventional two-dimensional memory (2D-M, whose memory cells are arranged on a 2-D plane, e.g., flash memory), although it is possible to form at least a peripheral-circuit component on a peripheral-circuit die instead of a 2D-array die, doing so will increase the overall cost and degrade the overall performance. This is because the 2D-array die and the peripheral-circuit die have similar BEOL structures, similar wafer costs and similar performance. Adding the extra bonding cost and delay, a discrete 2D-M has a higher cost and a slower speed than an integrated 2D-M. This is in sharp contrast to the 3D-M_{V}. The 3D-array die 30 and peripheral-circuit die 40 of a discrete 3D-M_{V} 50 have substantially different BEOL structures (e.g., different number of BEOL levels, different number of substrate interconnect levels, different substrate interconnect materials). As a result, a discrete 3D-M_{V} has a lower overall cost and a better overall performance than an integrated 3D-M_{V}.

Different from the integrated 3D-M_{V} 20, at least a peripheral-circuit component of the discrete 3D-M_{V} 50 is located on the peripheral-circuit die 40 instead of the 3D-array die 30. In other words, the peripheral-circuit components of 3D-M_{V} are partitioned between the 3D-array die 30 and the peripheral-circuit die 40. Several preferred partitioning schemes are disclosed in FIGS. 5A-9B.

FIGS. 5A-5B disclose a first preferred partitioning scheme. The discrete 3D-M_{V} 50 comprises a 3D-array die 30 and a peripheral-circuit die 40. In FIG. 5A, the 3D-array die 30 comprises a plurality of 3D-M_{V} arrays (e.g., 22aa, 22ay) and decoders. It also comprises an in-die V_{R}/V_{W}-generator 41. In FIG. 5B, the peripheral-circuit die 40 comprises at least an off-die A/D-translator 49, which is absent from the 3D-array die 30 of FIG. 5A. Without the V_{R}/V_{W}-generator 49, the 3D-array die 30 of FIG. 5A has a higher array efficiency. In another preferred embodiment, the 3D-array die 30 comprises an in-die A/D-translator, while the peripheral-circuit die 40 comprises an off-die V_{R}/V_{W}-generator, which is absent from the 3D-array die 30. Similarly, without the A/D-translator, the 3D-array die 30 of FIG. 5A has a higher array efficiency.

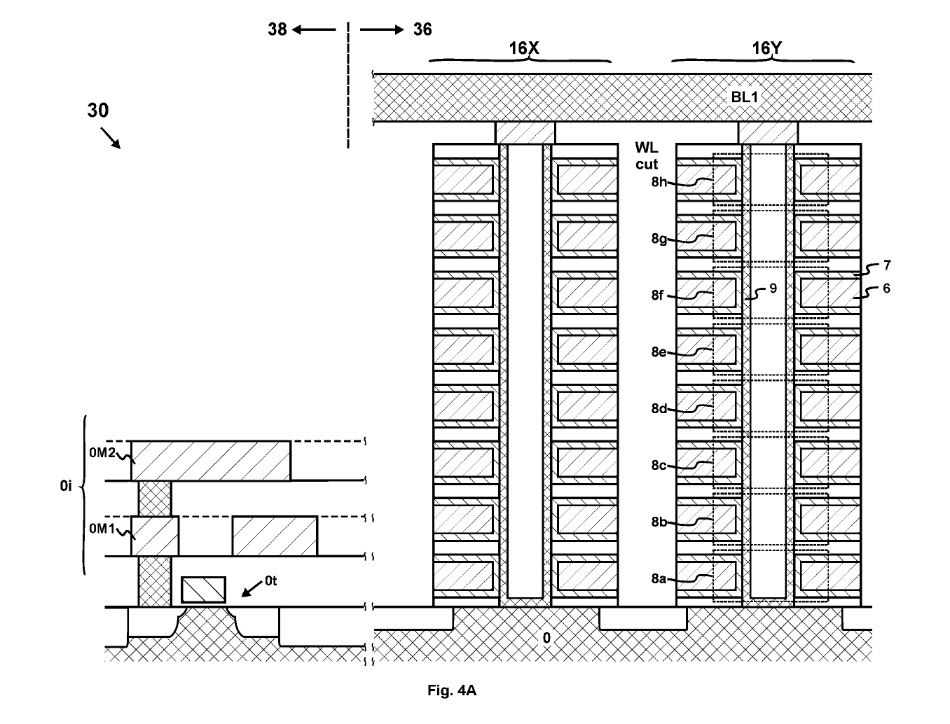

FIGS. 6A-6B disclose a second preferred partitioning scheme. The discrete 3D-M_{V} 50 comprises a 3D-array die 30 and a peripheral-circuit die 40. In FIG. 6A, the 3D-array die 30 comprises the 3D-M_{V} arrays (e.g., 22aa, 22ay) and their decoders, but does not comprise the V_{R}/V_{W}-generator 41 and the A/D-translator 49. In FIG. 6B, the peripheral-circuit die 40 comprises not only the A/D-translator 49, but also the V_{R}/V_{W}-generator 41. The 3D-array die 30 of FIG. 6A has a very high array efficiency. This leads to a substantially lower overall cost for the discrete 3D-M_{V}.

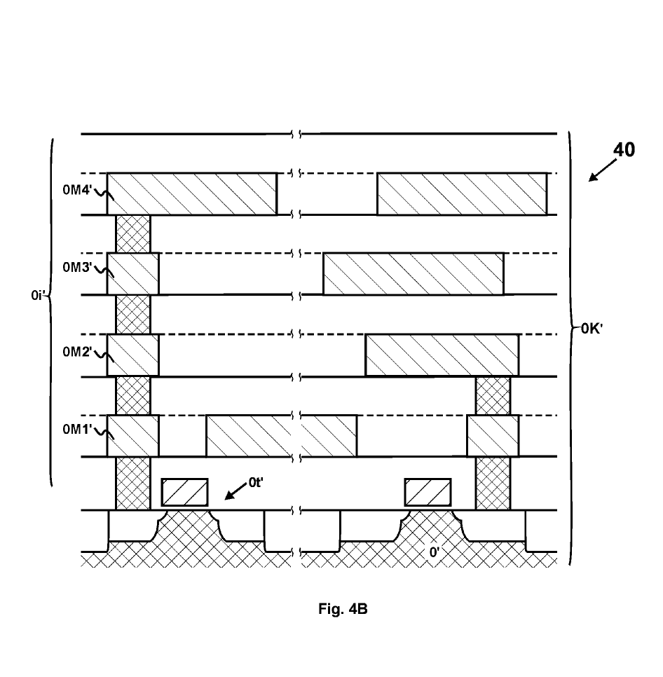

FIGS. 7A-7C disclose a third preferred partitioning scheme. The discrete 3D-M_{V} 50 comprises a 3D-array die 30, two peripheral-circuit dice 40, 40*. The 3D-array die 30 comprises 3D-M_{V} arrays (e.g., 22aa, 22ay) and their decoders, but does not comprise the V_{R}/V_{W}-generator 41 and the A/D-translator 49 (FIG. 7A). The V_{R}/V_{W}-generator 41 and the A/D-translator 49 are located on separate dice: the V_{R}/V_{W}-generator 41 is located on the peripheral-circuit die A 40 (FIG. 7B); the A/D-translator 49 is located on the peripheral-circuit die B 40* (FIG. 7C). As is well known to those skilled in the art, the V_{R}/V_{W}-generator is an analog-intensive circuit, whereas the A/D-translator is a digital-intensive circuit. Because they are located on separate dice, these circuits can be optimized independently: the peripheral-circuit die A 40 is optimized for analog performance, whereas the peripheral-circuit die B 40* is optimized for digital performance.

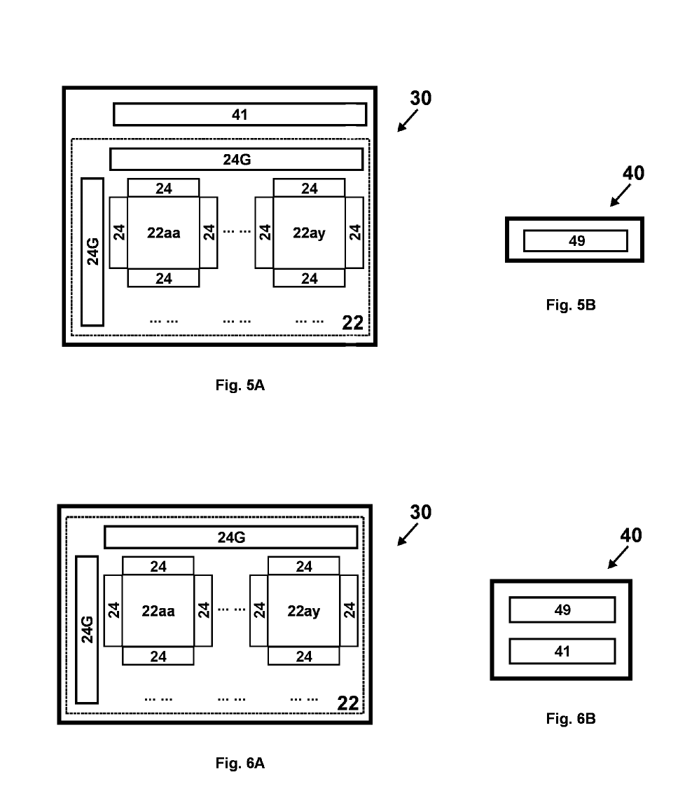

FIGS. 8A-8B disclose a fourth partitioning scheme. It is similar to those in FIGS. 6A-6B except that the 3D-array die 30 further comprises a first serializer-deserializer (SerDes) 47 (FIG. 8A). It converts parallel digital signals (e.g., address/data/command/status) inside the 3D-array die 30 to serial digital signals outside the 3D-array die 30 and vice versa. In the mean time, the peripheral-circuit die 40 comprise a second serializer-deserializer (SerDes) 47′ (FIG. 8B). It converts parallel digital signals (e.g., address/data/command/ status) inside the peripheral-circuit die 40 to serial digital signals outside the peripheral-circuit die 40 and vice versa. By serializing digital signals, the number of bond wires (or, solder bumps) can be reduced between the 3D-array die 30 and the peripheral-circuit die 40. This helps to lower the bonding cost.

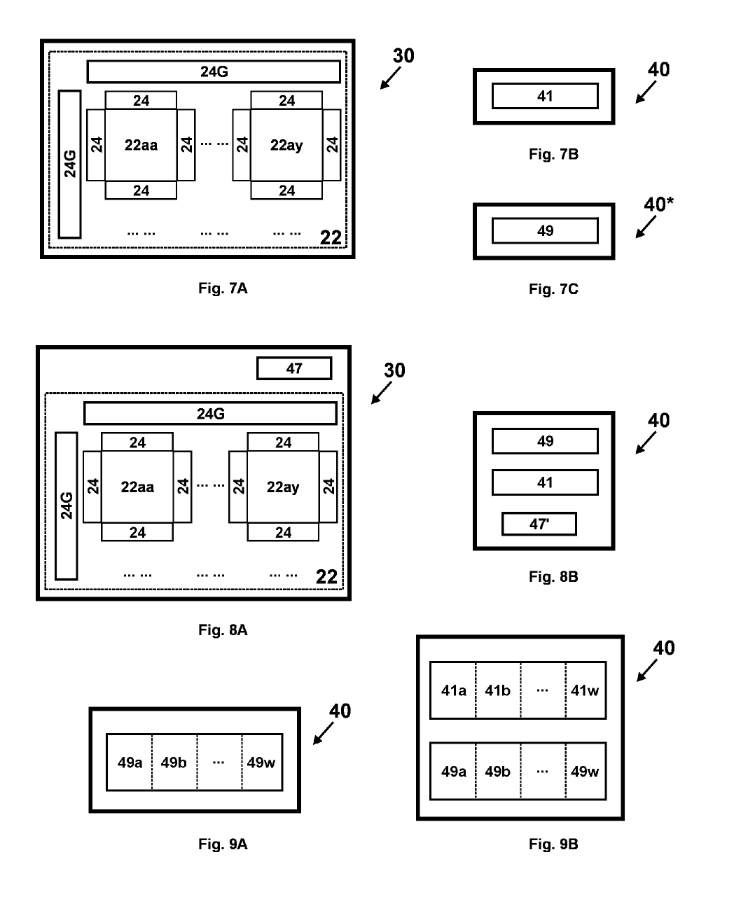

Referring now to FIGS. 9A-9B, two preferred peripheral-circuit dice 40 supporting multiple 3D-array dice are illustrated. The peripheral-circuit die 40 of FIG. 9A comprises a plurality of A/D-translators 49a, 49b . . . 49w (or, V_{R}/V_{W}-generators). Each A/D-translator (e.g., 49a) translates address/data for an associated 3D-array die (e.g., 30a of FIG. 3D). The preferred peripheral-circuit die 40 of FIG. 9B further comprises a plurality of V_{R}/V_{W}-generators 41a, 41b . . . 41w. Each V_{R}/V_{W}-generator (e.g., 41a) provides read/write-voltages to an associated 3D-array die (e.g., 30a of FIG. 3D).

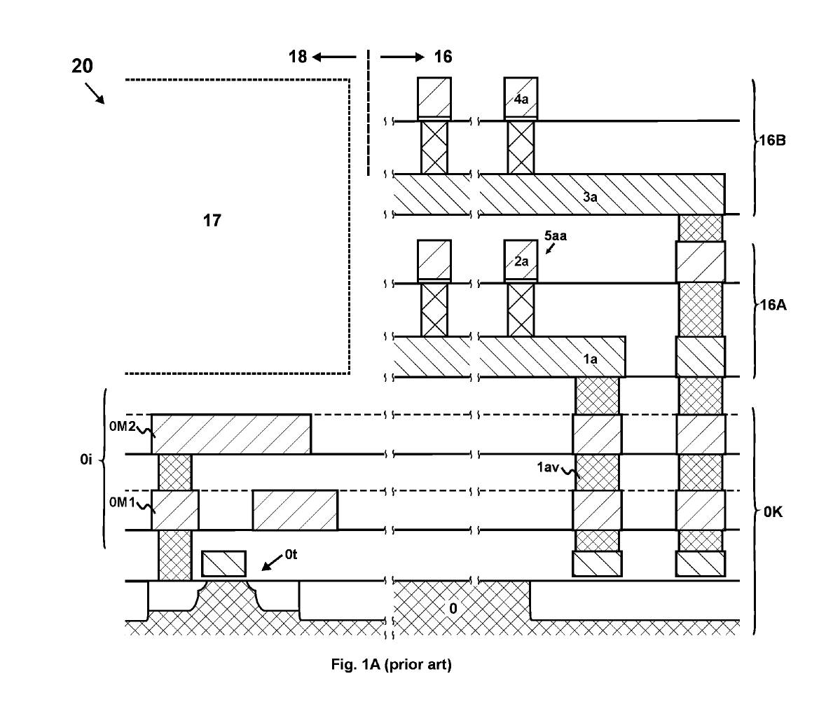

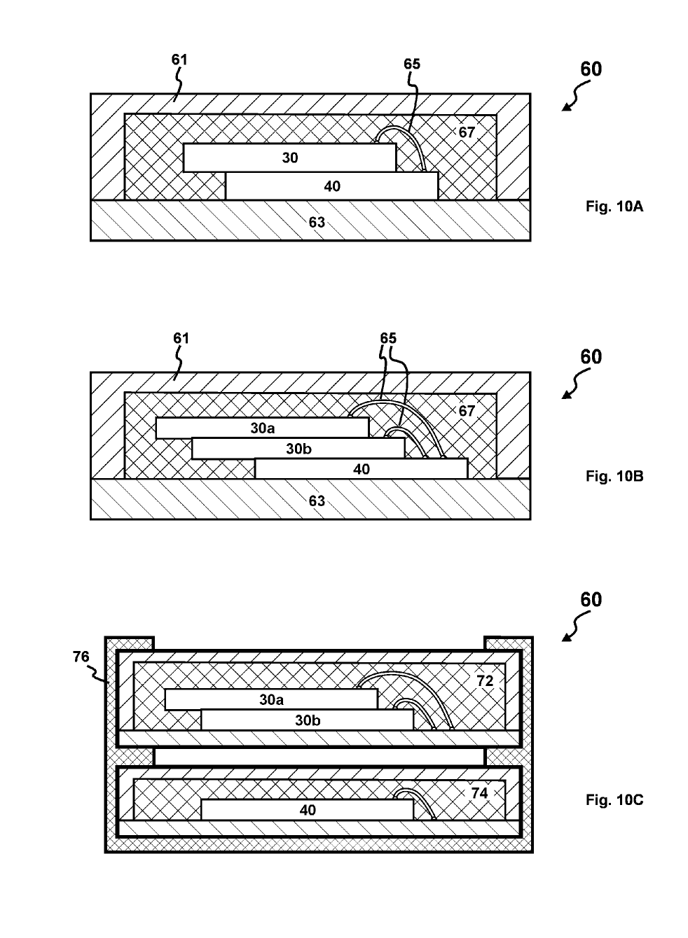

Referring now to FIG. 10A-10C, several preferred discrete 3D-Mᵥ packages (or, module) 60 are disclosed. The 3D-M_{V} packages in FIGS. 10A-10B are multi-chip package (MCP), while the 3D-M_{V} module in FIG. 1 OC is a multi-chip module (MCM). These MCP and MCM can be used as a memory card and/or a solid-state drive.

The preferred discrete 3D-M_{V} package 60 of FIG. 10A comprises two separate dice: a 3D-array die 30 and a peripheral-circuit die 40. These dice 30, 40 are vertically stacked on a package substrate 63 and located inside a package housing 61. Bond wires 65 provide electrical connection between the dice 30 and 40. Here, bond wire 65 provides a coupling means between the 3D-array die 30 and the peripheral-circuit die 40. Other exemplary coupling means include solder bump. To ensure data security, the dice 30, 40 are preferably encapsulated into a molding compound 67. In this preferred embodiment, the 3D-array die 30 is vertically stacked above the peripheral-circuit die 40. Alternatively, the peripheral-circuit die 40 can be vertically stacked above the 3D-array die 30; or, the 3D-array die 30 can be stacked face-to-face towards the peripheral-circuit die 40; or, the 3D-array die 30 can be mounted side-by-side with the peripheral-circuit die 40.

The preferred discrete 3D-M_{V} package 60 of FIG. 10B comprises two 3D-array dice 30a, 30b and a peripheral-circuit die 40. These dice 30a, 30b, 40 are three separate dice. They are located inside a package housing 61. The 3D-array die 30a is vertically stacked on the 3D-array die 30b, and the 3D-array die 30b is vertically stacked on the peripheral-circuit die 40. Bond wires 65 provide electrical connections between the dice 30A, 30B, and 40.

The preferred discrete 3D-M_{V} module 60 of FIG. 10C comprises a module frame 76, which houses two discrete packages, i.e., a 3D-array package 72 and a peripheral-circuit package 74. The 3D-array package 72 comprises two 3D-array dice 30a, 30b, while the peripheral-circuit package 74 comprises a peripheral-circuit die 40. The module frame 76 provides electrical connections between the 3D-array package 72 and the peripheral-circuit package 74 (not drawn in this figure).

While illustrative embodiments have been shown and described, it would be apparent to those skilled in the art that may more modifications than that have been mentioned above are possible without departing from the inventive concepts set forth therein. The invention, therefore, is not to be limited except in the spirit of the appended claims.

What is claimed is:

1. A discrete three-dimensional vertical memory (3D-M_{V}), comprising:
a 3D-array die comprising at least a 3D-M_{V} array, wherein said 3D-M_{V} array comprises a plurality of vertical memory strings, each of said vertical memory strings comprising a plurality of vertically stacked memory cells;
a peripheral-circuit die comprising at least an off-die peripheral-circuit component of said 3D-M_{V} array;
wherein said off-die peripheral-circuit component is absent from said 3D-array die; the number of memory cells on each of said vertical memory strings in said 3D-array die is substantially more than the number of interconnect levels in said peripheral-circuit die; and, said 3D-array die and said peripheral-circuit die are separate dice.

2. The memory according to claim 1, wherein said off-die peripheral-circuit component is selected from a group of peripheral-circuit components consisting of read-voltage generator, write-voltage generator, address translator and data translator.

3. The memory according to claim 1, wherein said 3D-array die further comprises at least an in-die peripheral-circuit component of said 3D-M_{V} array, and the number of interconnect levels of said off-die peripheral-circuit component is more than the number of interconnect levels of said in-die peripheral-circuit component.

4. The memory according to claim 1, wherein said 3D-array die further comprises at least an in-die peripheral-circuit component of said 3D-M_{V} array, and said off-die peripheral-circuit component and said in-die peripheral-circuit component comprise different interconnect materials.

5. The memory according to claim 1, wherein said 3D-M_{V} is a vertical-NAND.

6. The memory according to claim 1, wherein each of said memory cells comprises at least a vertical transistor.

7. The memory according to claim 1, wherein said 3D-M_{V} is a three-dimensional read-only memory (3D-ROM) or a three-dimensional random-access memory (3D-RAM).

8. The memory according to claim 1, wherein said 3D-array die and said peripheral-circuit die are located in a memory package, a memory module, a memory card, or a solid-state drive.

9. The memory according to claim 1, further comprising another 3D-array die including at least another 3D-M_{V} array, wherein said peripheral-circuit die comprises at least another portion of another off-die peripheral-circuit component for said another 3D-array die.

10. A discrete three-dimensional vertical memory (3D-M_{V}), comprising:
a 3D-array die comprising at least a 3D-M_{V} array and an in-die peripheral-circuit component of said 3D-M_{V} array, wherein said 3D-M_{V} array comprises a plurality of vertical memory strings, each of said vertical memory strings comprising a plurality of vertically stacked memory cells;
a peripheral-circuit die comprising at least an off-die peripheral-circuit component of said 3D-M_{V} array;
wherein said off-die peripheral-circuit component is absent from said 3D-array die; said off-die peripheral-circuit component and said in-die peripheral-circuit component comprise different interconnect materials; and, said 3D-array die and said peripheral-circuit die are separate dice.

11. The memory according to claim 10, wherein said off-die peripheral-circuit component is selected from a group of peripheral-circuit components consisting of read-voltage generator, write-voltage generator, address translator and data translator.

12. The memory according to claim 10, wherein said in-die peripheral-circuit component comprises high-temperature interconnect materials.

13. The memory according to claim 10, wherein said off-die peripheral-circuit component comprises high-speed interconnect materials.

14. The memory according to claim 10, wherein the number of memory cells on each of said vertical memory strings in said 3D-array die is substantially more than the number of interconnect levels in said peripheral-circuit die.

15. The memory according to claim 10, wherein the number of interconnect levels of said off-die peripheral-circuit component is more than the number of interconnect levels of said in-die peripheral-circuit component.

16. The memory according to claim 10, wherein said 3D-M_{V} is a vertical-NAND.

17. The memory according to claim 10, wherein each of said memory cells comprises at least a vertical transistor.

18. The memory according to claim 10, wherein said 3D-M_{V} is a three-dimensional read-only memory (3D-ROM) or a three-dimensional random-access memory (3D-RAM).

19. The memory according to claim 10, wherein said 3D-array die and said peripheral-circuit die are located in a memory package, a memory module, a memory card, or a solid-state drive.

20. The memory according to claim 10, further comprising another 3D-array die including at least another 3D-M_{V} array, wherein said peripheral-circuit die comprises at least another portion of another off-die peripheral-circuit component for said another 3D-array die.
